(19) United States
(12) Patent Application Publication
(10) Pub. No.: US 2017/0251572 A1
(43) Pub. Date: Aug. 31, 2017

(54) CIRCUIT CARD ASSEMBLY WITH THERMAL ENERGY REMOVAL

(71) Applicant: GE Intelligent Platforms, Inc., Charlottesville, VA (US)

(72) Inventors: Graham Charles KIRK, Towcester (GB); Shakti Singh CHAUHAN, Cupertino, CA (US); Stuart CONNOLLY, Towcester (GB); Zeshan Jabar HUSSAIN, Towcester (GB)

(21) Appl. No.: 15/517,153

(22) PCT Filed: Oct. 6, 2014
(86) PCT No.: PCT/US2014/059309

§ 371 Date: Apr. 5, 2017

(51) Int. Cl. H05K 7/20; H05K 7/14

(52) U.S. Cl. CPC H05K 7/20509; H05K 7/1404; H05K 7/20336; H05K 7/20309

(57) ABSTRACT

A circuit card assembly includes a heat sink, a locking mechanism, and a thermal insert. The heat sink couples to a circuit board and has an upper surface and a lower surface. The heat sink has a channel extending downwards along the upper surface thereof. The locking mechanism is disposed within the channel and includes a plurality of solid wedges movably arranged within the channel. Movement of the wedges is effective to secure the circuit card assembly to a holder. The thermal insert is disposed within the heat sink and is an elongated member. The thermal insert is configured to contact a portion of at least one of the solid wedges, thus assisting in removing a first amount of thermal energy from the circuit board.

### BACKGROUND OF THE INVENTION

Field of the Invention

The subject matter disclosed herein relates circuit card assemblies and specifically to removing thermal energy from circuit card assemblies associated with or coupling to these assemblies.

Brief Description of the Related Art

Circuit card assemblies are used for various purposes in today's electronic systems. The circuit card assemblies may include microprocessors (or other integrated circuits), or passive components such as resistors, capacitors, or inductors to mention a few examples. These circuit card assemblies are often arranged in a chassis. As the circuit card assemblies are operated, heat is generated by the electrical components disposed on these cards. Even if the components are not damaged by the heat, the operation of the circuit card assemblies may become inefficient due to the presence of heat. If this heat is not removed, it may cause damage to the circuit card assemblies or other devices that are near the circuit card.

Circuit card assemblies are held in place to the chassis by various types of locking arrangements. One such locking arrangement are wedge locks attached to the edges of the circuit card assembly. The wedge lock retains the circuit card assembly in the chassis and is a standardized design that fits within a chassis. The wedge lock provides one path for heat to be removed from the circuit board to the chassis.

The configuration of the heat sinks may result in restrictions to the flow of heat escaping the system in various sections Due to the dimensional constraints of the wedge lock and the circuit card assembly themselves and other factors, it is not uncommon for heat flow paths to reduce substantially in size. This type of sizing reduces thermal transfer in the system such that the performance of the circuit card assembly is reduced or components are damaged.

Previous attempts have been made to increase dimensions of areas of thermal flow, but often involved re-arranging the standard layout of the wedge lock assembly. Additionally, attempts have been made to provide thermal inserts coupled to the heat sink to assist in the removal of heat. However, because circuit boards have components of various dimensions, there is oftentimes an imperfect fit of the thermal insert, which in turn may lead to reduced effectivity. Further, these inserts are oftentimes comprised thermally due to limited space in existing designs. As a result, high-performance circuit boards may not be used because of the inability to effectively transfer heat.

Brief Description of the Invention

The present approaches incorporate the wedge lock design with a heat sink having a low resistance thermal shunt or highway. The heat sink design is dimensioned so as to mechanically obviate tolerance issues associated with associating thermal shunts into the thermal interface without affecting thermal performance. By configuring the wedge lock to contact a portion of the thermal shunt, the thermal shunt will in turn exert a force against the heat sink while the wedge locking mechanism maintains solid contact with the chassis. As such, increased thermal dissipation may occur, allowing for higher powered circuit boards to be used as desired. Additionally, because the wedge lock is in contact exclusively with the thermal insert, it will not be affected by tolerance issues between the thermal insert and the heat sink.

In many of these embodiments, a circuit card assembly is provided which includes a heat sink, a locking mechanism, and a thermal insert disposed within the heat sink. The heat sink is thermally coupled to a circuit board and has an upper surface and a lower surface and a longitudinal channel extending downward along the upper surface.

The locking mechanism is disposed within the longitudinal channel of the heat sink and includes a plurality of solid wedges movably arranged within the longitudinal channel. The solid wedges are formed without openings or channels there through. The longitudinal movement of the solid wedges within the channel is effective to secure the circuit card assembly to an external holder.

The thermal insert is disposed within the heat sink and includes an elongated member. The thermal insert is configured to contact a portion of at least one of the solid wedges of the locking mechanism to assist in removing a first amount of thermal energy from the circuit board. Upon engaging the locking mechanism, the thermal insert engages the solid wedge and further thermally engages the heat sink to provide the thermal path.

In other aspects, the thermal insert may include a rotatable portion that is configured to rotatably protrude from the thermal insert to come in contact with the thermal insert. As such, the thermal insert may provide a precise thermal connection to the circuit board. This rotatable portion may include a number of visual indicators corresponding to the amount of protrusion from the thermal insert to further assist in determining the correct amount of protrusion required to create a thermal connection with the circuit board.

In other aspects, heat pipe or other member may be coupled to the thermal insert. This heat pipe is configured to passively dissipate thermal energy from the circuit board. In yet other aspects, the thermal insert may include a first and a second material. The first material may remove the first amount of thermal energy from the circuit board in a first direction, and the second material may remove the first amount of thermal energy from the circuit board in a second direction. In some forms, the first material may be one of aluminum and copper, and the second material may be graphite. In other examples, other materials or thermal solutions may be used.

In other aspects, the rod may be provided that extends longitudinally through the heat sink and forms an isothermal section. The rod may be constructed of a material different from the heat sink. By “isothermal section,” it is meant the temperature is evenly dispersed across the distance of the rod and the surrounding heat sink, which allows thermal energy to be more efficiently removed from the circuit board assembly.

In some aspects, a thermal path is formed from the circuit board through the heat sink to the lower surface of the heat sink. In these aspects, the thermal path is effective to remove a second amount of thermal energy away from the circuit board.

In some aspects, a bottom surface of each of the plurality of wedges is generally flat. In other aspects, the locking apparatus further includes a screw apparatus that is configured to, upon actuation, move the plurality of wedges.

In other aspects, a second thermal insert is provided that is disposed within the heat sink. This second thermal insert contacts a portion of a different one of the solid wedges to assist in removing thermal energy from the circuit board. In some forms, the thermal insert spans the width of the heat sin. Thus, in these forms, the thermal insert contacts a portion of at least one solid wedge in a second locking mechanism on the opposing side of the locking mechanism.

In others of these embodiments, a circuit card assembly includes a heat sink, a locking mechanism, a thermal insert, a first thermal path, a second thermal path, and a third thermal path. The heat sink has a first portion and a second portion. The first portion is thermally coupled to the circuit board and the first and second portions are formed integrally together and connected via an integral neck portion. The heat sink includes an upper surface and a lower surface. The heat sink further includes a longitudinal channel extending downward along the upper surface of the heat sink.

The locking mechanism is disposed within the longitudinal channel of the heat sink and includes a plurality of solid wedges movably arranged within the longitudinal channel. The solid wedges are formed without openings there through. Longitudinal movement of the plurality of solid wedges within the channel is effective to secure the circuit card assembly to an external holder.

The thermal insert is disposed within the heat sink and extends across the first and second portions thereof. The thermal insert comprises an elongated member and is configured to contact a portion of at least one solid wedge to assist in securing the circuit card assembly to the external holder.

The first thermal path is formed from the circuit board through the first portion of the heat sink, through the neck, through the second portion of the heat sink, to the lower surface of the heat sink in contact with the external holder. The first thermal path is effective to remove a first amount of thermal energy away from the circuit board.

The second thermal path is formed from the circuit board, through the first portion of the heat sink, through the second portion of the heat sink, and then through at least some of the plurality of solid wedges to the holder. The second thermal path is effective to remove a second amount of thermal energy from the circuit board that is a leakage amount roughly an order of magnitude less than the first amount associated with the first thermal path.

The third thermal path is formed from the circuit board and through the thermal insert and through the solid wedge that the thermal insert is in contact with. The third thermal path is effective to remove a third amount of thermal energy away from the circuit board.

### BRIEF DESCRIPTION OF THE DRAWINGS

For a more complete understanding of the disclosure, reference should be made to the following detailed description and accompanying drawings wherein:

FIG. 1 comprises a perspective view of a circuit card assembly according to various embodiments of the present invention;

FIG. 2 comprises a perspective view of the circuit card assembly of FIG. 1 according to various embodiments of the present invention;

FIG. 3 comprises a cross sectional view of the circuit card assembly of FIGS. 1-2 according to various embodiments of the present invention;

FIG. 4 comprises a perspective view of the circuit card assembly of FIGS. 1-3 according to various embodiments of the present invention;

FIG. 5 comprises a cross sectional view of the circuit card assembly of FIGS. 1-4 according to various embodiments of the present invention;

FIG. 6 comprises a perspective view of the circuit card assembly of FIGS. 1-5 according to various embodiments of the present invention;

FIG. 7 comprises a front view of the circuit card assembly of FIGS. 1-6 according to various embodiments of the present invention;

FIG. 8 comprises a perspective view of a circuit card assembly with a rod according to various embodiments of the present invention;

FIG. 9 comprises a perspective view of the circuit card assembly of FIG. 8 according to various embodiments of the present invention;

FIG. 10 comprises a cross sectional view of the circuit card assembly of FIGS. 8-9 according to various embodiments of the present invention;

FIG. 11 comprises a perspective view of the circuit card assembly of FIGS. 8-10 according to various embodiments of the present invention;

FIG. 12 comprises a cross-sectional view of the circuit card assembly of FIGS. 8-11 according to various embodiments of the present invention;

FIG. 13 comprises a perspective view of the circuit card assembly of FIGS. 8-12 according to various embodiments of the present invention;

FIG. 14 comprises a front view of the circuit card assembly of FIGS. 8-13 according to various embodiments of the present invention;

FIG. 15 comprises a front perspective view of a circuit card assembly according to various embodiments of the present invention;

FIG. 16 comprises a right side perspective view of the circuit card assembly of FIG. 15 according to various embodiments of the present invention;

FIG. 17 comprises a cross sectional view of the circuit card assembly of FIGS. 15-16 according to various embodiments of the present invention;

FIG. 18 comprises a lower perspective view of the circuit card assembly of FIGS. 15-17 according to various embodiments of the present invention;

FIG. 19 comprises a perspective view of the circuit card assembly of FIGS. 15-18 according to various embodiments of the present invention;

FIG. 20 comprises a lower perspective view of an alternative thermal insert according to various embodiments of the present invention;

FIG. 21 comprises an upper perspective view of an alternative thermal insert according to various embodiments of the present invention;

FIG. 22 comprises a lower perspective view of the alternative thermal insert of FIG. 21 according to various embodiments of the present invention; and

FIG. 23 comprises a lower perspective view of an alternate thermal insert according to various embodiments of the present invention; and

FIG. 24 comprises a front view of a group of circuit card assemblies assembled in a chassis according to various embodiments of the present invention.

Skilled artisans will appreciate that elements in the figures are illustrated for simplicity and clarity. It will further be appreciated that certain actions and/or steps may be described or depicted in a particular order of occurrence while those skilled in the art will understand that such specificity with respect to sequence is not actually required. It will also be understood that the terms and expressions used herein have the ordinary meaning as is accorded to such terms and expressions with respect to their corresponding respective areas of inquiry and study except where specific meanings have otherwise been set forth herein.

### DETAILED DESCRIPTION OF THE INVENTION

The approaches described herein provide an improved circuit card assembly having a locking arrangement (e.g., a locking wedge approach) that combines with a thermal insert to provide increased thermal dissipation. This results in increased efficiency in dissipating heat while maintaining conventional size constraints.

In other aspects, tolerances between the circuit card and the thermal insert are decreased upon securing the locking mechanism to the chassis. The thermal connection between the thermal insert and the heat sink is increased an additional thermal path is created through the thermal insert and to the wedges that are used in the locking mechanism thereby further reducing the overall thermal resistance of the system.

By maintaining existing sizing standards, these approaches can be implemented in existing configurations without requiring modifications to circuit card assembly chassis. Thus, the overall layout of current systems is not disturbed. Further, when the circuit operates at a reduced temperature, the speed of microprocessors (and/or other electrical components) may be increased. This advantage may be used to keep the temperature of critical devices on the circuit board under their junction temperature limit when running at elevated environmental temperatures or to increase the speed of the processor whilst staying below the junction temperature.

To give a specific example of the application of the present approaches, a neck of approximately 3 mm or more is created for the thermal path in a locking wedge-type circuit card assembly apparatus. In one example and when the circuit board attached to the assembly includes a microprocessor, the present approaches reduce the temperature of the microprocessor by approximately 2.5 degrees centigrade. The larger neck section that is created also allows for incorporating heat spreading devices (such as copper rods, heat pipes, thermal ground planes, and graphite rods to mention a few examples) into the assembly. The thermal insert provides an additional thermal path for heat to dissipate through. These additional heat-spreading devices spread the heat along the entire width of the assembly and further reduce the temperature of the attached circuit card (and the components deployed on the card).

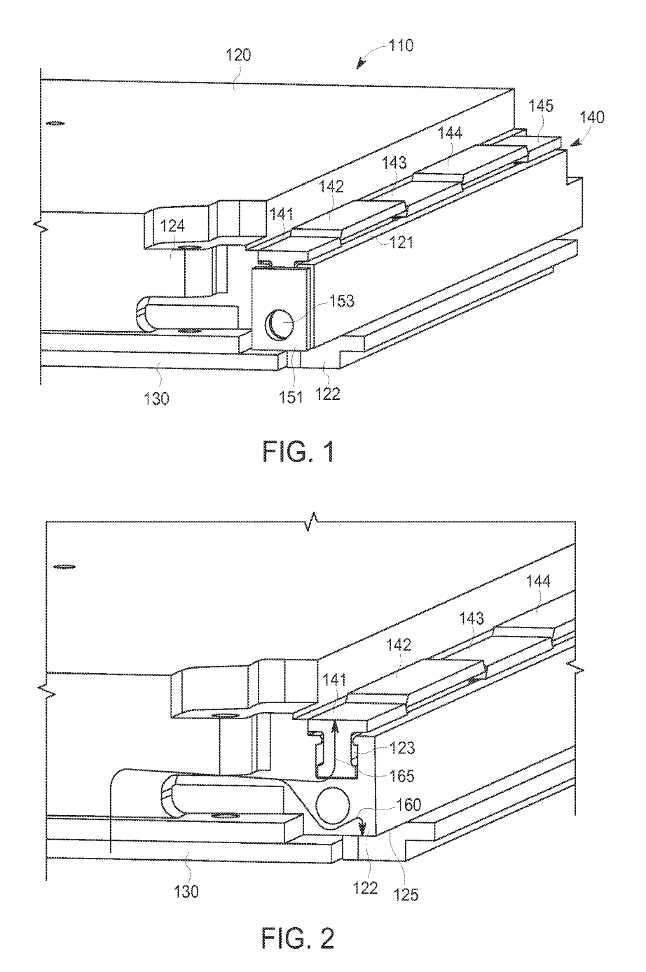

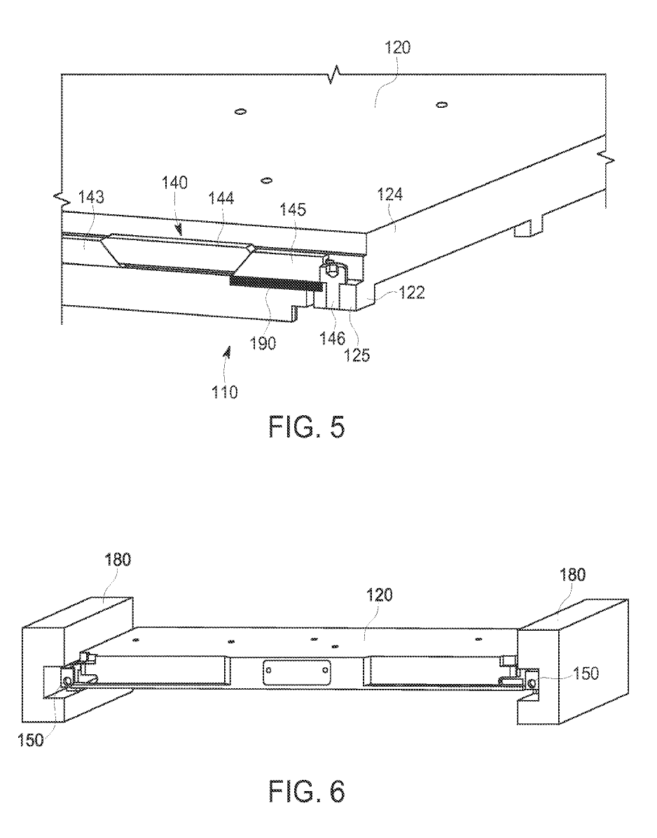

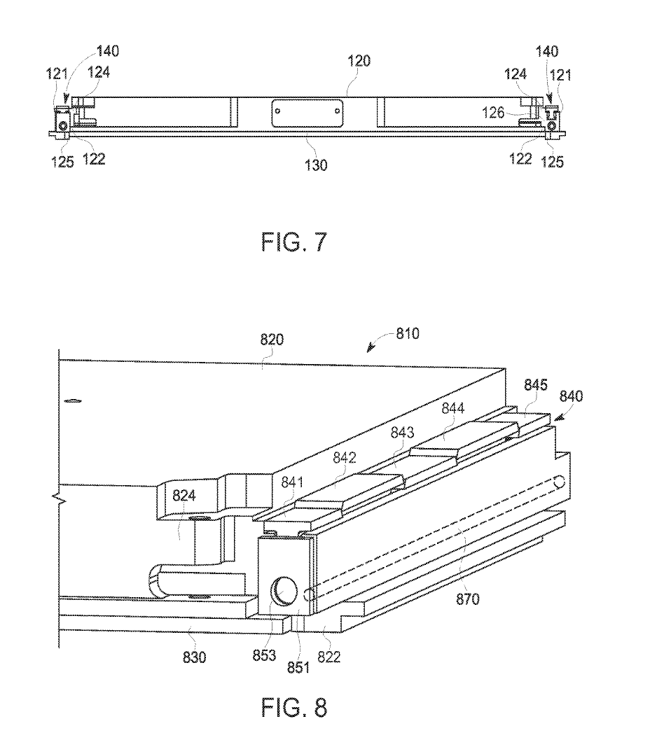

Referring now to FIGS. 1-7, one example of a circuit card assembly 110 is described. The circuit card assembly 110 includes a heat sink 120, a circuit board 130, a locking mechanism 140, a first thermal path 160, a second thermal path 165, and a thermal insert 190. The heat sink 120 has a first portion 124 and a second portion 125. The first portion 124 is coupled to the circuit board 130. The first portion 124 and the second portion 125 are formed integrally together and connected via an integral neck portion 126.

The heat sink 120 is constructed of aluminum or other metals having similar thermal characteristics. In one example, the integral neck portion 126 of the circuit card assembly 110 is increased in dimensions to approximately 3.47 mm×1.85 mm, thereby increasing the thermal path for thermal energy exiting the circuit board 130.

The heat sink 120 includes an upper surface 121 and a lower surface 122. The heat sink 120 further includes a longitudinal channel 123 extending downward along the upper surface 121 of the heat sink 120. The dimensions of the longitudinal channel 123 are approximately 120 mm long and 4 mm deep, in one example. It is understood that the longitudinal channel 123 may alternatively be positioned on the lower surface 122 and extend upwards along this lower surface 122 and that other dimensions are possible.

The circuit board 130 is any type of circuit board that has a variety of different components. For example, various resistors, integrated circuits, capacitors, are disposed on the circuit board 130. These components generate heat that is dispersed according to the present approaches. The circuit board 130 includes a circuit board external connector (not shown for simplicity) to provide the circuit board 130 with electrical power and to allow the transmission of data. The circuit board external connector may be one of several commonly-used connectors, for example, Vita 46 and 48 Standard connectors (VPX), Versa Module Eurocard (VME) connectors, or Compact PCi (CPCi) connectors. Skilled artisans will appreciate that a number of different connections may be utilized to transmit power and data to and from the circuit board 130.

The locking mechanism 140 is disposed within the longitudinal channel 123 of the heat sink 120 and includes a first solid wedge 141, a second solid wedge 142, a third solid wedge 143, a fourth solid wedge 144, and a fifth solid wedge 145 that are all movably arranged within the longitudinal channel 123. It will be appreciated that in other examples, there may be more or less than five solid wedges. The first solid wedge 141, second solid wedge 142, third solid wedge 143, fourth solid wedge 144, and fifth solid wedge 145 are formed without openings there through (e.g., they are solid) and longitudinal movement of the plurality of solid wedges within the channel is effective to secure the circuit card assembly 110 to an external holder 180. In some examples, each of a plurality of wedges are generally T-shaped in the cross section. In other examples, each of the plurality of wedges are generally J-shaped in a cross section. Other cross-sectional shapes may also be used. In some aspects, a bottom surface of each of the plurality of wedges is generally flat. The wedges are constructed of aluminum or other metals having similar thermal characteristics. In one example, the wedges are approximately 21 mm tall, 4.8 mm wide, and 4.75 mm deep. Other dimensions are possible.

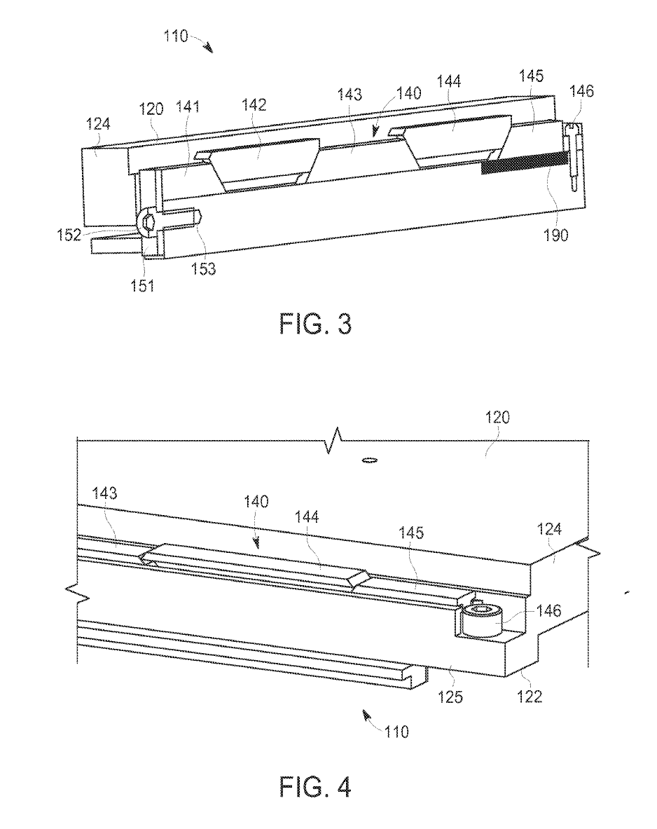

With exception to the front surface of the first solid wedge 141 and the rear-most surface of the fifth solid wedge 145, adjoining surfaces of the wedges are angled at approximately 45 degrees from vertical as shown in the cross sectional view of FIG. 3. More specifically, in the first solid wedge 141, third solid wedge 143, and fifth solid wedge 145, the approximately 45 degree angle from vertical results in the wedges having an acute angle of approximately 45 degrees. In the second solid wedge 142 and the fourth solid wedge 144, the approximately 45 degree angle from vertical results in the wedges having an obtuse angle of approximately 135 degrees.

The external holder 180 is generally “C” or “U” shaped and can be constructed of a metal. The protruding surfaces of the external holder 180 are configured to be planar. The external holder 180 is integral or attached to the chassis through conventional methods including, for example, bolting, screwing, gluing, or other methods.

In some aspects, the locking mechanism 140 includes a stopper 146 (e.g., a bolt or screw constructed of stainless steel which is inserted into the heat sink 120 to halt movement of the plurality of wedges along the longitudinal channel 123. The head of the stopper 146 protrudes from the heat sink 120, and maintains contact with the rear surface of the fifth solid wedge 145 to restrict movement of the fifth solid wedge 145 and thus the locking mechanism (described in detail below). Other locking mechanisms are possible.

In other aspects, the locking mechanism 140 further includes a screw apparatus 150 that is configured to, upon actuation, move the plurality of wedges. The screw apparatus 150 includes the screw apparatus plate 151, screw 152, and threaded screw channel 153. The screw apparatus plate 151 contains a hole through which the screw 152 is inserted, and is further inserted into the threaded screw channel 153. Thus, the screw apparatus plate 151 is positioned between the head of the screw 152 and the heat sink 120. The rear surface of the screw apparatus plate 151 is in contact with the front surface of the first solid wedge 141. The screw apparatus plate 151 and screw 152 are constructed of stainless steel. The threaded screw channel 153 extends a distance of approximately 20 mm into the heat sink 120. Other locking mechanisms are possible.

The thermal insert 190 is disposed within the heat sink 120 and comprises an elongated member. In some examples, the thermal insert 190 spans the entire width of the heat sink 120. In other examples, the thermal insert 190 spans less than the entire width of the heat sink 120. The thermal insert 190 is in thermal communication with the circuit board 130 to dissipate energy therefrom. The thermal insert 190 is in thermal communication with at least one solid wedge to complete the thermal path. The thermal insert 190 may be disposed to be in thermal communication with any number of the wedges and at any location along the wedges.

In other aspects, to lock the circuit card assembly 110 to the external holder 180, a user rotates the screw 152 into the threaded screw channel 153, which causes the screw apparatus plate 151 to affect a force against the first solid wedge 141 in the direction of the longitudinal channel 123. In response to this force, the first solid wedge 141 moves in the longitudinal channel 123 and presses against the second solid wedge 142, the second solid wedge 142 moves in the longitudinal channel 123 and presses against the third solid wedge 143, and so on until the fifth solid wedge 145 presses against the stopper 146.

Because the stopper 146 restricts further movement of the wedges into the longitudinal channels, upon tightening the screw 152 into the threaded screw channel 153, the fifth solid wedge 145 exerts a force against the rear surface of the fourth solid wedge 144. Because the rear surface of the fourth solid wedge 144 is angled at approximately 45 degrees from vertical and forms an obtuse angle of approximately 135 degrees, the force exerted by the fifth solid wedge 145 provides a force on the fourth solid wedge 144 causing it to rise in the direction perpendicular to the longitudinal channel 123.

As the screw 152 is further tightened, the fourth solid wedge 144 continues to rise in the direction perpendicular to the longitudinal channel 123 until the topmost surface of the fourth solid wedge 144 comes in contact with and presses against the inner surface of the external holder 180. This resistive force exerted by the external holder 180 causes the first solid wedge 141 to move toward the third solid wedge 143. As a result of this rotation of the screw 152, the distance between the first solid wedge 141, third solid wedge 143, and fifth solid wedge 145 is reduced. Because the front and rear surfaces of the second solid wedge 142 are angled at approximately 45 degrees from vertical and form obtuse angles of approximately 135 degrees and the rear surface of the first solid wedge 141 and the front surface of the third solid wedge 143 form supplementary angles with those of the second solid wedge 142, the forces exerted by the first solid wedge 141 and the third solid wedge 143 cause the second solid wedge 142 to rise in a direction perpendicular to the longitudinal channel 123.

When the fourth solid wedge 144 and subsequently the second solid wedge 142 rise in the direction perpendicular to the longitudinal channel 123, the topmost surfaces of these wedges come in contact with and press against the inner surface of the external holder 180. Upon further rotating the screw 152, thus further raising the second solid wedge 142, the external holder 180 exerts an opposite retention force on the wedges, which results in the circuit card assembly 110 being secured to the external holder 180 which is secured to the chassis. The circuit card assembly 110 is therefore clamped in the external holder 180 between the lower surface 122 of the heat sink 120 and the second solid wedge 142 and fourth solid wedge 144.

The first thermal path 160 is formed from the circuit board 130 through the first portion 124 of the heat sink 120, through the integral neck portion 126 of the heat sink 120, through the second portion 125 of the heat sink 120, to the lower surface 122 of the heat sink 120. The first thermal path 160 is effective to remove a first amount of thermal energy away from the circuit board 130. This is accomplished because the lower surface 122 of the heat sink 120 is in contact with the external holder 180, which creates a thermal interface allowing for thermal energy to be removed to the external holder 180.

The integral neck portion 126 of the heat sink 120 is of dimensions sufficient to prevent a creation of a significant thermal resistance between the first portion 124 and the second portion 125 of the heat sink 120. For example, the neck dimensions can vary between approximately 2 mm and 6 mm to accomplish this function.

The second thermal path 165 is formed from the circuit board 130, through the first portion 124 of the heat sink 120, through the integral neck portion 126 of the heat sink 120, through the second portion 125 of the heat sink 120, and then through at least some of the first solid wedge 141, second solid wedge 142, third solid wedge 143, fourth solid wedge 144, and fifth solid wedge 145 to the external holder 180. The second thermal path 165 is effective to remove a second amount of thermal energy from the circuit board 130 that is greater than a leakage amount. This is accomplished because the top surfaces of the wedges in contact with the external holder 180 create a thermal interface allowing for thermal energy to be removed.

It is understood that the term “thermal interface” is to describe any cooperation of component surfaces which, when in direct or close contact with one another, allow for thermal energy to be transferred there between. This may involve the additional use of paste, pads, tape, films, soldering or other existing methods.

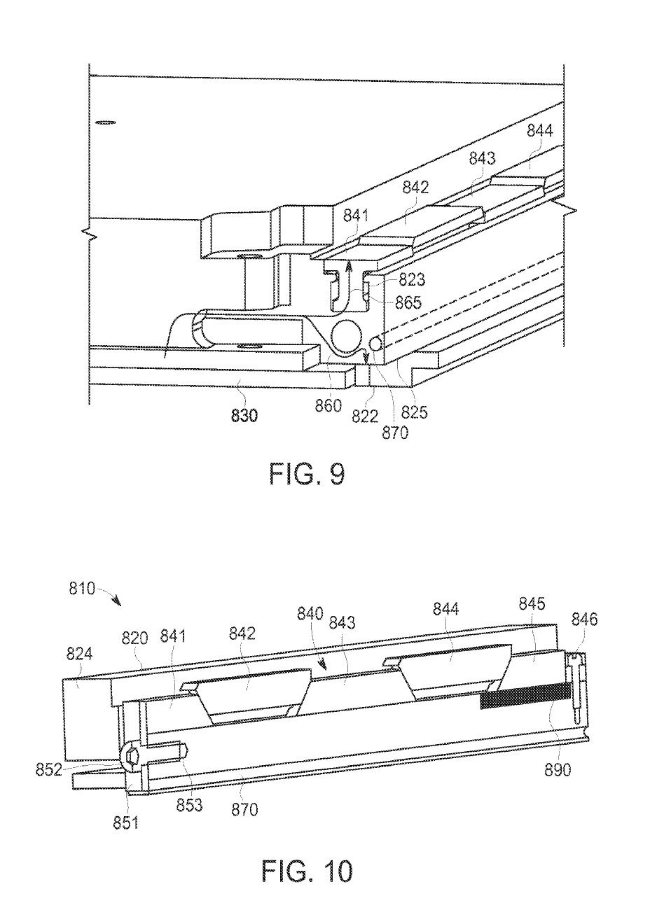

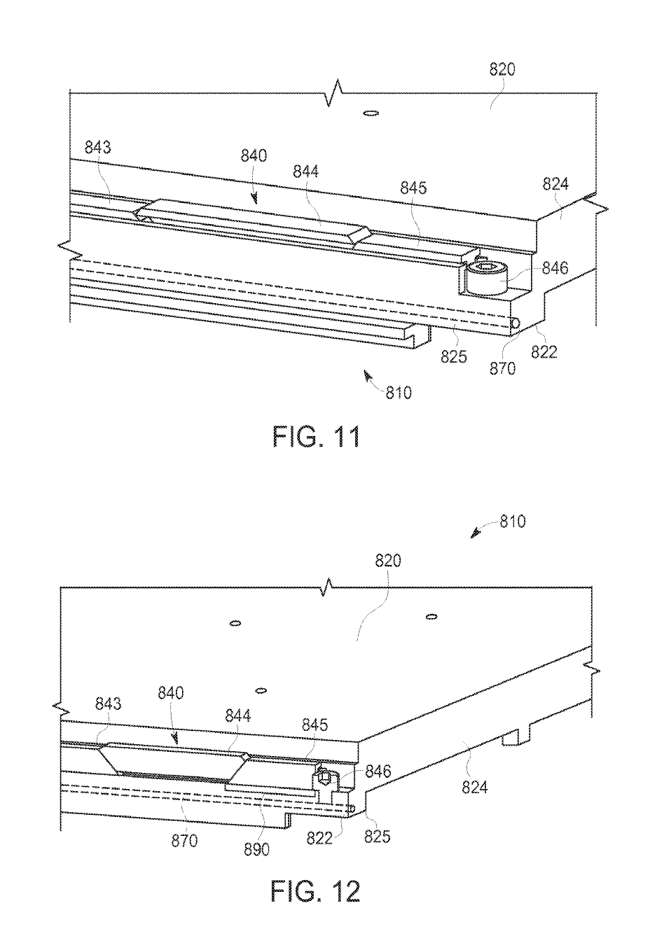

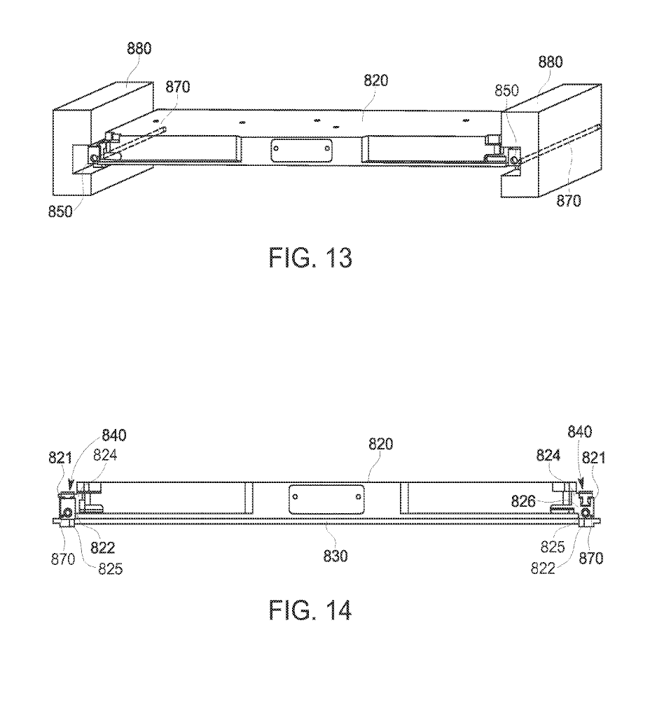

Referring now to FIGS. 8-14, another example of a circuit card assembly 810 is described. The circuit card assembly 810 includes a heat sink 820, a locking mechanism 840, a first thermal path 860, a second thermal path 865, and a thermal insert 890. The heat sink 820 has a first portion 824 and a second portion 825. The first portion 824 is coupled to the circuit board 830 and the first portion 824 and second portion 825 are formed integrally together and connected via an integral neck portion 826.

The heat sink 820 is constructed of aluminum or other metals having similar thermal characteristics. The integral neck portion 826 is increased to approximately 3.47 mm×1.85 mm, thereby increasing the thermal path for thermal energy exiting the circuit board 830.

The heat sink 820 includes an upper surface 821 and a lower surface 822. The heat sink 820 further includes a longitudinal channel 823 extending downward along the upper surface 821 of the heat sink 820. The dimensions of the longitudinal channel 823 are approximately 120 mm long and 4 mm deep, in one example. Other dimensions are possible

The circuit board 830 is any type of circuit board that has a variety of different components. For example, various resistors, integrated circuits, capacitors, are disposed on the circuit board 830. These components generate heat that is dispersed according to the present approaches. The circuit board 830 includes a circuit board external connector (not shown for simplicity) to provide the circuit board 830 with electrical power and to allow the transmission of data. The circuit board external connector may be one of several commonly-used connectors, for example VPX, VME, or CPCi connectors. Skilled artisans will appreciate that a number of different connections may be utilized to transmit power and data to and from the circuit board 830.

The locking mechanism 840 is disposed within the longitudinal channel 823 of the heat sink 820 and includes a plurality of a first solid wedge 841, a second solid wedge 842, a third solid wedge 843, a fourth solid wedge 844, and a fifth solid wedge 845 movably arranged within the longitudinal channel 823. The wedges are formed without openings there through (e.g., they are solid) and longitudinal movement of the plurality of solid wedges within the channel is effective to secure the circuit card assembly 810 to an external holder 880. In some examples, the wedges are generally T-shaped in a cross section. In other examples, each of the plurality of wedges are generally J-shaped in a cross section. Other cross-sectional shapes may also be used. In some aspects, a bottom surface of each of the plurality of wedges is generally flat. The wedges are constructed of aluminum or other metals having similar thermal characteristics. In one example, the wedges are approximately 21 mm tall, 4.8 mm wide, and 4.75 mm deep. Other dimensions are possible.

With exception to the front surface of the first solid wedge 841 and the rear-most surface of the fifth solid wedge 845, adjoining surfaces of the wedges are angled at approximately 45 degrees from vertical as shown in the cross sectional view of FIG. 10. More specifically, in the first solid wedge 841, third solid wedge 843, and fifth solid wedge 845, the approximately 45 degree angle from vertical results in the wedges having an acute angle of approximately 45 degrees. In the second solid wedge 842 and the fourth solid wedge 844, the approximately 45 degree angle from vertical results in the wedges having an obtuse angle of approximately 135 degrees.

The external holder 880 is generally “C” or “U” shaped and can be constructed of a metal. The protruding surfaces of the external holder 880 are configured to be planar. The external holder 880 is integral or attached to the chassis through conventional methods including, for example, bolting, screwing, gluing, or other methods.

In some aspects, the locking mechanism 840 includes a stopper 846 is a bolt or screw constructed of stainless steel which is inserted into the heat sink 820 to halt movement of the plurality of wedges along the longitudinal channel 823. The head of the stopper 846 protrudes from the heat sink 820, and maintains contact with the rear surface of the fifth solid wedge 845 to restrict movement of the fifth solid wedge 845 and thus the locking mechanism.

In other aspects, the locking mechanism 840 further includes a screw apparatus 850 that is configured to, upon actuation, move the plurality of wedges. The screw apparatus 850 includes the screw apparatus plate 851, screw 852, and threaded screw channel 853. The screw apparatus plate 851 contains a hole through which the screw 852 is inserted, and is further inserted into the threaded screw channel 853. Thus, the screw apparatus plate 851 is positioned between the head of the screw 852 and the heat sink 820. The rear surface of the screw apparatus plate 851 is in contact with the front surface of the first solid wedge 841. The screw apparatus plate 851 and screw 852 are constructed of stainless steel. The threaded screw channel 853 extends a distance of approximately 20 mm into the heat sink 820.

The thermal insert 890 is disposed within the heat sink 820 and comprises an elongated member. In some examples, the thermal insert 890 spans the entire width of the heat sink 820. In other examples, the thermal insert 890 spans less than the entire width of the heat sink 820. The thermal insert 890 is in thermal communication with the circuit board 830 to dissipate energy therefrom. The thermal insert 890 is in thermal communication with at least one solid wedge to complete the thermal path. The thermal insert 890 may be disposed to be in thermal communication with any number of the wedges and at any location along the wedges.

In still other aspects, to lock the circuit card assembly 810 to the external holder 880, a user rotates the screw 852 into the threaded screw channel 853, which causes the screw apparatus plate 851 to affect a force against the first solid wedge 841 in the direction of the longitudinal channel 823. In response to this force, the first solid wedge 841 moves in the longitudinal channel 823 and presses against the second solid wedge 842, the second solid wedge 842 moves in the longitudinal channel 823 and presses against the third solid wedge 843, and so on until the fifth solid wedge 845 presses against the stopper 846.

Because the stopper 846 restricts further movement of the wedges into the longitudinal channels, upon tightening the screw 852 into the threaded screw channel 853, the fifth solid wedge 845 exerts a force against the rear surface of the fourth solid wedge 844. Because the rear surface of the fourth solid wedge 844 is angled at approximately 45 degrees from vertical and forms an obtuse angle of approximately 135 degrees, the force exerted by the fifth solid wedge 845 provides a force on the fourth solid wedge 844 causing it to rise in the direction perpendicular to the longitudinal channel 823.

As the screw 852 is further tightened, the fourth solid wedge 844 continues to rise in the direction perpendicular to the longitudinal channel 823 until the topmost surface of the fourth solid wedge 844 comes in contact with and presses against the inner surface of the external holder 880. This resistive force exerted by the external holder 880 causes the first solid wedge 141 to move toward the third solid wedge 843. As a result of this rotation of the screw 852, the distance between the first solid wedge 841, third solid wedge 843, and fifth solid wedge 845 is reduced. Because the front and rear surfaces of the second solid wedge 842 are angled at approximately 45 degrees from vertical and form obtuse angles of approximately 135 degrees and the rear surface of the first solid wedge 841 and the front surface of the third solid wedge 843 form supplementary angles with those of the second solid wedge 842, the forces exerted by the first solid wedge 841 and the third solid wedge 843 cause the second solid wedge 842 to rise in a direction perpendicular to the longitudinal channel 823.

When the fourth solid wedge 844 and subsequently the second solid wedge 842 rise in the direction perpendicular to the longitudinal channel 823, the topmost surfaces of these wedges come in contact with and press against the inner surface of the external holder 880. Upon further rotating the screw 852, thus further raising the second solid wedge 842, the external holder 880 exerts an opposite retention force on the wedges, which results in the circuit card assembly 810 being secured to the external holder 880 which is secured to the chassis. The circuit card assembly 810 is therefore clamped in the external holder 880 between the lower surface 822 of the heat sink 820 and the second solid wedge 842 and fourth solid wedge 844.

A rod 870 constructed of a material different from the heat sink 820, extends longitudinally through the heat sink 820 and forms an isothermal section in the heat sink 820. In some examples, the rod 870 is cylindrical and has a diameter of approximately 4 mm. In some examples, the rod 870 is placed approximately 2 mm below the locking mechanism 840. In some examples, the rod 870 is constructed of copper. In some aspects, the use of the rod 870 creates an isothermal section in the heat sink 820. By isothermal section, it is meant the temperature surrounding the rod 870 in the heat sink 820 is evenly dispersed across the entire length of the rod 870 which allows thermal energy to be more efficiently removed from the circuit board 830.

The first thermal path 860 is formed from the circuit board 830 through the first portion 824 of the heat sink 820, through the integral neck portion 826 of the heat sink 820, through the second portion 825 of the heat sink 820, to the lower surface 822 of the heat sink 820. The first thermal path 860 is effective to remove a first amount of thermal energy away from the circuit board 830. This is accomplished because the lower surface 822 of the heat sink 820 is in contact with the external holder 880, which creates a thermal interface allowing for thermal energy to be removed to the external holder 880.

The integral neck portion 826 of the heat sink 820 is of dimensions sufficient to prevent a creation of a significant thermal resistance between the first portion 824 and the second portion 825 of the heat sink 820. For example, the neck dimensions can vary between approximately 2 mm and 6 mm.

The second thermal path 865 is formed from the circuit board 830, through the first portion 824 of the heat sink 820, through the integral neck portion 826 of the heat sink 820, through the second portion 825 of the heat sink 820, and then through at least some of the first solid wedge 841, second solid wedge 842, third solid wedge 843, fourth solid wedge 844, and fifth solid wedge 845 to the external holder 880. The second thermal path 865 is effective to remove a second amount of thermal energy from the circuit board 830 that is greater than a leakage amount.

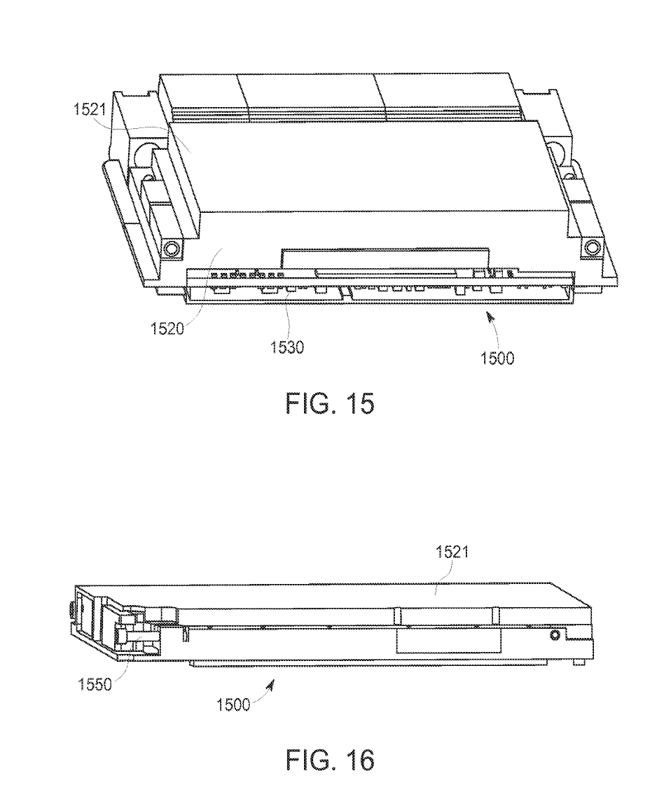

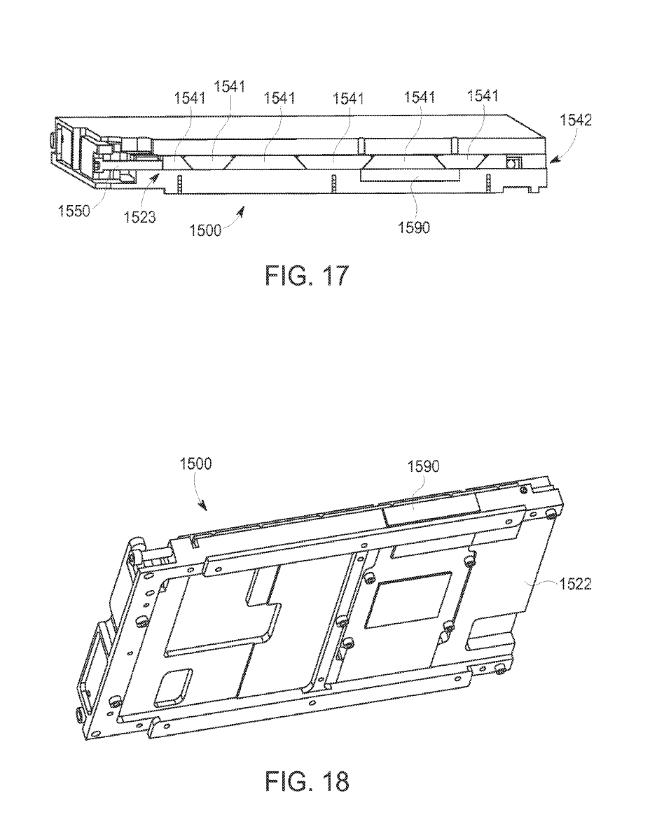

Turning to FIGS. 15-23, alternative systems are provided. Features and/or elements in these systems which serve a largely identical purpose to those described with regards to the previous systems and apparatuses have identical two-digit suffixes (e.g. heat sink 120, 1520) as those provided previously. Accordingly, some features will not be discussed in substantial detail.

Referring now to FIGS. 15-19, one example of a circuit card assembly 1500 is described. The circuit card assembly 1500 includes a circuit board 1530, a heat sink 1520 having an upper surface 1521, a lower surface 1522, and a longitudinal channel 1523 extending downward along the upper surface 1521, a locking mechanism 1540 which includes solid wedges 1541 and a screw 1550, and a thermal insert 1590.

The heat sink 1520 may be constructed of aluminum or other metals having desirable thermal characteristics. The locking mechanism 1540 is disposed within the longitudinal channel 1523 of the heat sink 1520 and includes any number of solid wedges 1541. In one example five solid wedges 1541 are used in the circuit card assembly 1500. It will be appreciated that in other examples, there may be more than or fewer than five solid wedges. The solid wedges 1541 are formed without openings there through. Longitudinal movement of the plurality of solid wedges 1541 within the longitudinal channel 1523 is effective to secure the circuit card assembly 1500 to an external holder.

The circuit board 1530 is any type of circuit board that has a variety of different components. For example, various resistors, integrated circuits, capacitors, and other components are disposed on the circuit board 1530. These components generate heat that is dispersed according to the present approaches. The circuit board 1530 includes a circuit board external connector (not shown for simplicity) to provide the circuit board 1530 with electrical power and to allow the transmission of data. The circuit board external connector may be one of several commonly-used connectors, for example, Vita 46 and 48 Standard connectors (VPX), Versa Module Eurocard (VME) connectors, or Compact PCi (CPCi) connectors. Skilled artisans will appreciate that a number of different connections may be utilized to transmit power and data to and from the circuit board 1530.

The thermal insert 1590 is disposed within the heat sink 1520 and comprises an elongated member. In some examples, the thermal insert 1590 spans the entire width of the heat sink 1520. In other examples, the thermal insert 1590 spans less than the entire width of the heat sink 1520. The thermal insert 1590 is in thermal communication with the circuit board 1530 to dissipate energy therefrom. The thermal insert 1590 is in thermal communication with at least one solid wedge 1541 to complete the thermal path. The thermal insert 1590 may be disposed to be in thermal communication with any number of the wedges 1541 and at any location along the wedges 1541.

The wedges are constructed of aluminum or other metals having similar thermal characteristics. In some aspects, a bottom surface of each of the wedges is generally flat to contact the thermal insert 1590. Thus, the thermal insert 1590 is in physical communication with at least one solid wedge 1541 to assist in creating a strong thermal path between the circuit board 1530, thermal insert 1590, and wedge 1541.

The screw 1550 is configured to, upon actuation, move the wedges 1541. As described above, the plate positioned between the screw 1550 and the wedge 1541 assists in moving the wedges 1541. Other locking mechanisms are possible.

In operation, to lock the circuit card assembly 1500 to the external holder, a user rotates the screw 1550, which causes the plate to affect a force against the first wedge 1541 in the direction of the longitudinal channel 1523. In response to this force, the first wedge 1541 moves in the longitudinal channel 1523 presses against the second wedge 1541 which causes it to move upwards and into the longitudinal channel 1523, causing the third wedge 1541 to move downwards and into the longitudinal channel 1523, and so on until the wedges 1541 press against a surface on the opposite side of the longitudinal channel 1523 configured to restrict movement thereof.

As the screw 1550 is tightened, wedges 1541 move upwards or downwards in the longitudinal channel 1523 depending on their configuration. The wedge 1541 contacting the thermal insert 1590 pushes downwards to come in further contact with the thermal insert. As a result of this downward force, the thermal insert 1590 also pushes downwards against the heat sink 1520 and the circuit board 1530 until a solid thermal connection is formed. It is understood that in some examples, the thermal insert 1590 may come in direct physical contact with the circuit board 1530, and alternatively, a commonly-known thermal conductor may be disposed between the thermal insert 1590 and the circuit board 1530. Other examples are possible. So configured, the wedge 1541 exclusively contacts the thermal insert 1590, and thus is not affected by any tolerance issues between the thermal insert 1590 and the heat sink 1520, resulting in a strong thermal connection therebetween. The thermal insert 1590 may remove a first amount of thermal energy from the circuit board 1530 to the wedges 1541 and to the connecting chassis.

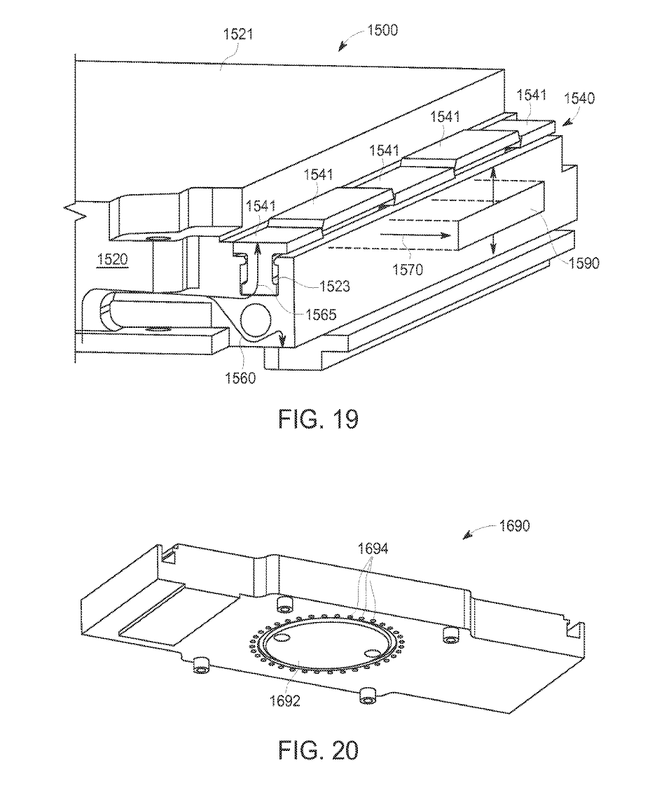

In some examples and as illustrated in FIG. 19, different thermal paths are created within the circuit card assembly 1500. In these examples, a first thermal path 1560 is formed from the circuit board 1530 through a first portion of the heat sink 1520, through an integral neck portion, through a second portion, and then through the lower surface of the heat sink 1520. This first thermal path 1560 removes a first amount of thermal energy away from the circuit board 1530. A second thermal path 1565 is formed from the circuit board 1530, through the first portion of the heat sink 1520, through the second portion of the heat sink, and then through any number of wedges 1541 to the external holder. This second thermal path 1565 is effective to remove a second amount of thermal energy from the circuit board 1530 that is greater than a leakage value. A third thermal path 1570 is formed from the circuit board 1530 through the thermal insert 1590. In some examples, the thermal path may end at the thermal insert 1590, and in other examples, the third thermal path 1524 may continue through the wedge 1541 in contact with the thermal insert 1590.

The integral neck portion of the heat sink 1520 is of dimensions sufficient to prevent a creation of a significant thermal resistance between the first and second portions of the heat sink 1520. For example, the neck dimensions can vary between approximately 2 mm and 6 mm to accomplish this function.

Referring now to FIG. 20, an alternative thermal insert 1690 is described. The thermal insert 1690 includes a rotatable portion 1692 and visual indicators 1694 surrounding the rotatable portion 1692. It is understood that the thermal insert 1690 functions in a similar manner to thermal insert 1690, and accordingly its configuration or operation will not be described in further detail.

The rotatable portion 1692 of the thermal insert 1690 is configured to rotatably protrude from the thermal insert 1690 to contact the circuit board. As such, the rotatable portion 1692 may be threaded which corresponds to threading contained on the heat sink to allow for this motion.

To operate the rotatable portion 1692, a user may utilize any number of methods such as simply twisting the rotatable portion by hand. In other examples, the user may engage a screwdriver or other rotating tool to twist the rotatable portion downward. Other examples are provided.

In some forms, the visual indicators 1694 may be used to assist in determining the amount of protrusion desired. For example, upon placing the heat sink on the circuit board, the user may measure the distance between the circuit board and the thermal insert. As visual indicators 1694 correspond to a defined amount of protrusion, the user will know precisely how much rotation is necessary to limit or eliminate the gap between the thermal insert 1690 and the circuit board. As a result, tolerances between the thermal insert 1690 and the circuit board will be reduced, resulting in a better thermal connection to remove heat from the circuit board.

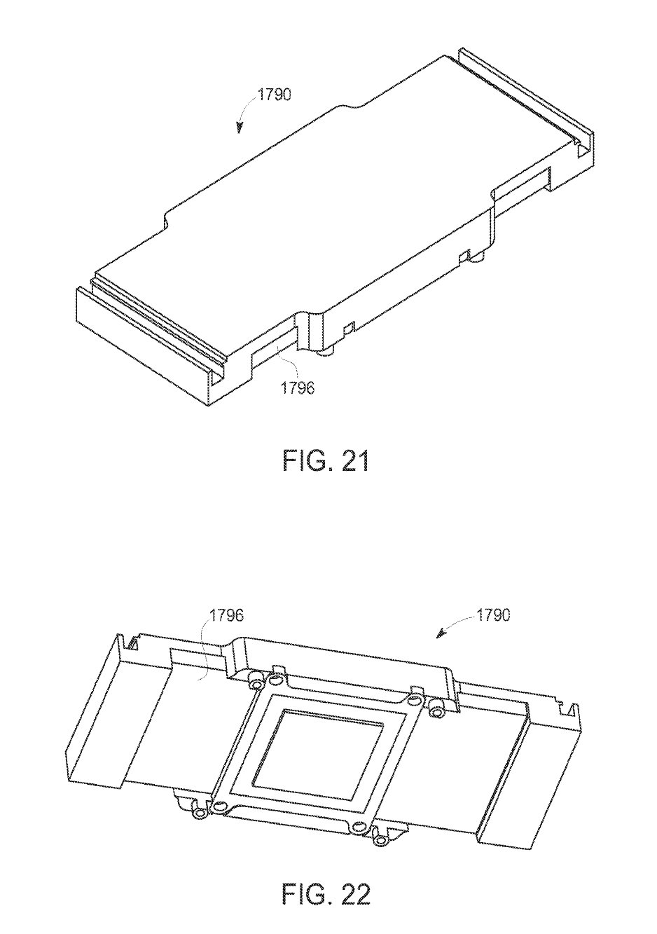

Referring to FIGS. 21 & 22, an alternate thermal insert 1790 is described. The thermal insert 1790 includes a heat pipe 1796 coupled to the thermal insert 1790. The heat pipe 1796 may be configured to passively dissipate thermal energy from the circuit board, thus creating an even more efficient thermal dissipation apparatus. A non-limiting example of such a heat pipe 1796 is herein described, but it is understood that any such configuration known by those having skill in the art may be utilized.

The heat pipe 1796 is generally tubular in shape and passively transfers heat in an efficient manner by utilizing the latent heat of vaporization, the latent heat of condensation, and capillary action. The heat pipe 1796 consists of a low pressure hollow chamber which draws a vacuum due to a pressure differential. As a result, water contained in the heat pipe may boil at a lower boiling temperature. When the circuit board is powered, heat is generated, thus causing the water inside the heat pipe 1796 to evaporate. Due to the pressure difference in the chamber, vapor will move away from the heat source to extreme ends of the chamber. At this point, the vapor will condense, and the wicking structure will wick water back to the heat source by capillary action. In some forms, the heat pipe may alternatively be a generally flat or cuboidal vapor chamber.

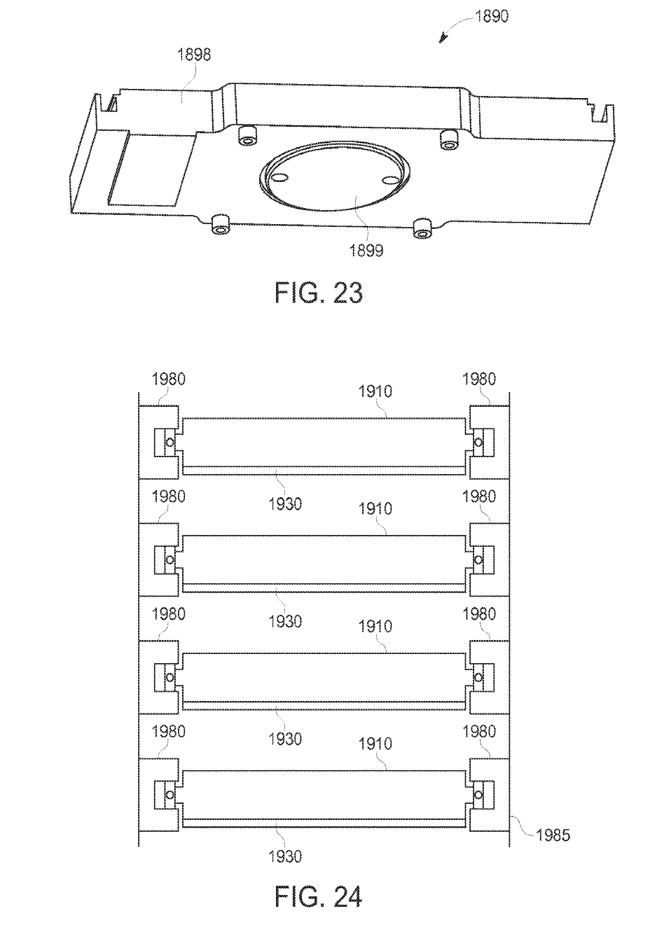

Referring to FIG. 23, an alternate thermal insert 1890 is described. In these forms, the thermal insert may be made of a number of different materials to assist in thermal dissipation. For example, a first portion 1898 may be constructed of a first material configured to remove heat more efficiently in a particular direction, and a second portion 1899 may be constructed of a second material configured to remove heat more efficiently in a second particular direction. Because the thermal insert 1890 is generally constructed in layers, thermal energy dissipates in a planar direction. Accordingly, by utilizing materials with high thermal conductivity in certain directions, heat will be dissipated to the outermost edges of the thermal insert 1890. Additionally, due to the weight of traditional materials, lighter materials having similar thermal conductivities may provide the benefit of a lighter system. It is understood that any number of configurations and/or shapes of the different materials are envisioned.

In one example, the second material may include the rotatable portion described previously. As such, by combining these materials in the thermal insert 1890, efficient thermal dissipation may occur. The first material may be, for example, aluminum, copper, or other metals or combinations thereof, and the second material may be, for example, graphite or similar materials having similar thermal dissipation properties.

In some forms, the thermal insert 1890 may extend to the edge of the heat sink and be integrally formed to include the longitudinal channel which support the locking mechanisms. In some forms, the thermal insert 1890 may include a heat pipe, vapor chamber, or other vapor space used by persons having skill in the relevant art.

Referring now to FIG. 24, an example of a circuit card chassis that uses the assemblies of FIGS. 1-7, FIGS. 8-14, and/or FIGS. 15-23 is described. A chassis 1985 includes a plurality of circuit card assemblies 1910. The circuit card assemblies 1910 include the circuit board 1930 and circuit board external connector (not shown in the drawings for simplicity) and are connected to the chassis 1985 through holders 1980. The circuit card assemblies 1910 are restrained in the holders 1980 through the previously-mentioned locking mechanism (e.g., the locking mechanism 140 described with regards to FIGS. 1-7 herein). The circuit card assemblies 1910 slide into the holders 1980, whereupon the locking mechanism is rotated which creates the clamping restraining force on the circuit card assemblies 1910.

By inserting the circuit card assemblies 1910 in the holders 1980 and chassis 1985, thermal energy is removed from the circuit card assemblies 1910 to the holders 1980 and ultimately to the chassis 1985. This passive cooling allows the circuit card assemblies 1910 to operate in a more efficient manner.

In one example, the running temperature of hot devices on the circuit board are reduced by several degrees centigrade. These lower operating temperatures allow the circuit boards to be used at higher speeds with reduced concern for avoiding critical temperatures.

It will be appreciated by those skilled in the art that modifications to the foregoing embodiments may be made in various aspects. Other variations clearly would also work, and are within the scope and spirit of the invention. The present invention is set forth with particularity in the appended claims. It is deemed that the spirit and scope of that invention encompasses such modifications and alterations to the embodiments herein as would be apparent to one of ordinary skill in the art and familiar with the teachings of the present application.

What is claimed is:

1. A circuit card assembly, comprising:
a heat sink, the heat sink being coupled to a circuit board, the heat sink having an upper surface and a lower surface, the heat sink having a longitudinal channel extending downward along the upper surface of the heat sink;
a locking mechanism disposed within the longitudinal channel of the heat sink, the locking mechanism comprising a plurality of solid wedges movably arranged within the longitudinal channel, each of the plurality of solid wedges formed without openings or channels there through, wherein a longitudinal movement of the plurality of solid wedges within the longitudinal channel is effective to secure the circuit card assembly to an external holder;
a thermal insert disposed within the heat sink, the thermal insert comprising an elongated member and being configured to contact a portion of at least one of the plurality of solid wedges to assist in removing a first amount of thermal energy from the circuit board.

2. The circuit card assembly of claim 1, wherein the thermal insert comprises a rotatable portion configured to rotatably protrude from the thermal insert to contact the circuit board.

3. The circuit card assembly of claim 2, wherein the rotatable portion comprises a plurality of indicators corresponding to an amount of protrusion from the thermal insert to assist in determining a correct amount of protrusion therefrom.

4. The circuit card assembly of claim 1, comprising a vapor chamber coupled to the thermal insert, the vapor chamber configured to passively dissipate thermal energy from the circuit board.

5. The circuit card assembly of claim 1, wherein the thermal insert comprises a first material and a second material.

6. The circuit card assembly of claim 5, wherein the first material is configured to remove the first amount of thermal energy from the circuit board in a first direction and the second material is configured to remove the first amount of thermal energy in a second direction.

7. The circuit card assembly of claim 1, comprising a thermal path formed from the circuit board through the heat sink to the lower surface of the heat sink, the thermal path being effective to remove a second amount of thermal energy away from the circuit board.

8. The circuit card assembly of claim 1, comprising a heat pipe, the heat pipe constructed of a material different from the heat sink, the heat pipe extending longitudinally through the heat sink and forming an isothermal section in the heat sink.

9. The circuit card assembly of claim 5 wherein the first material comprises at least one of aluminum and copper.

10. The circuit card assembly of claim 9, wherein the second material comprises graphite.

11. The circuit card assembly of claim 1 wherein a bottom surface of each of the plurality of solid wedges is generally flat.

12. The circuit card assembly of claim 1 wherein the locking mechanism comprises a screw apparatus that is configured to, upon actuation, move the plurality of solid wedges.

13. The circuit card assembly of claim 1, further comprising a second thermal insert disposed within the heat sink and being configured to contact a portion of a different one of the plurality of solid wedges to assist in removing thermal energy from the circuit board.

14. The circuit card assembly of claim 1, wherein the thermal insert is configured to span a width of the heat sink such that the thermal insert contacts a portion of at least one solid wedge in a second locking mechanism on the opposite side of the locking mechanism.

15. A circuit card assembly, comprising:
a heat sink having a first portion and a second portion, the first portion coupling to a circuit board, the first portion and the second portion formed integrally together and connected via an integral neck portion, the heat sink with an upper surface and a lower surface, the heat sink including a longitudinal channel extending downward along the upper surface of the heat sink;
a locking mechanism disposed within the longitudinal channel of the heat sink, the locking mechanism comprising a plurality of solid wedges movably arranged within the longitudinal channel, each of the plurality of solid wedges formed without openings there through, wherein a longitudinal movement of the plurality of solid wedges within the longitudinal channel is effective to secure the circuit card assembly to an external holder;
a thermal insert disposed within the heat sink and extending across the first portion and the second portion thereof, the thermal insert comprising an elongated member and being configured to contact a portion of at least one of the plurality of solid wedges to assist in securing the circuit card assembly to the external holder;
a first thermal path formed from the circuit board through the first portion of the heat sink, through the integral neck portion, through the second portion of the heat sink, to the lower surface of the heat sink, the first thermal path being effective to remove a first amount of thermal energy away from the circuit board;
a second thermal path formed from the circuit board, through the first portion of the heat sink, through the second portion of the heat sink, and then through at least some of the plurality of solid wedges to the external holder, the second thermal path effective to remove a second amount of thermal energy from the circuit board that is greater than a leakage amount;
a third thermal path formed from the circuit board through the thermal insert, the third thermal path being effective to remove a third amount of thermal energy away from the circuit board.

16. The circuit card assembly of claim 15, wherein the integral neck portion of the heat sink is of dimensions sufficient to prevent a creation of a significant thermal resistance between the first portion and the second portion of the heat sink.

17. The circuit card assembly of claim 15, wherein the thermal insert comprises a rotatable portion configured to rotatably protrude from the thermal insert to contact the circuit board.

18. The circuit card assembly of claim 17, wherein the rotatable portion comprises a plurality of indicators corresponding to an amount of protrusion from the thermal insert to assist in determining a correct amount of protrusion therefrom.

19. The circuit card assembly of claim 15, comprising a heat pipe coupled to the thermal insert, the heat pipe configured to passively dissipate thermal energy from the circuit board.

20. The circuit card assembly of claim 15, wherein the thermal insert comprises a first material and a second material, the first material configured to remove the first amount of thermal energy from the circuit board in a first direction, the second material configured to remove the first amount of thermal energy in a second direction.
